(19) United States
(12) Patent Application Publication
(10) Pub. No.: US 2026/0016555 A1
(43) Pub. Date: Jan. 15, 2026

(54) METHOD FOR GENERATING A MOTION-CORRECTED MAGNETIC RESONANCE IMAGE DATASET

(71) Applicant: Siemens Healthineers AG, Forchheim (DE)

(72) Inventors: Daniel Polak, Erlangen (DE); Daniel Nicolas Splitthoff, Uttenreuth (DE); Stephen Farman Cauley, Winchester, MA (US); Bryan Clifford, Belmont, MA (US)

(21) Appl. No.: 19/266,592

(22) Filed: Jul. 11, 2025

(30) Foreign Application Priority Data
Jul. 12, 2024 (EP) 24188261

(51) Int. Cl. G01R 33/565; G01R 33/56

(52) U.S. Cl. CPC G01R 33/56509; G01R 33/5608

(57) ABSTRACT

A method for generating a motion-corrected magnetic resonance image dataset of a body region of a subject, the method comprising receiving magnetic resonance data acquired of the body region; receiving information on the body region covered by the magnetic resonance image dataset; weighting at least part of the received magnetic resonance data by reducing the signal originating from parts of the body region that are expected to have undergone non-rigid and/or independent motion during the acquisition, thereby producing weighted magnetic resonance data; and estimating the motion-corrected image dataset by minimizing the data consistency error between the magnetic resonance data acquired in the imaging protocol and a forward model described by an encoding matrix, wherein the encoding matrix includes motion parameters, Fourier encoding, and optionally subsampling and/or coil sensitivities of a multi-channel coil array, wherein the estimation includes at least one step of estimating motion parameters from the weighted magnetic resonance data.

### CROSS REFERENCE TO RELATED APPLICATIONS

This application claims the benefit of EP24188261.2 filed on Jul. 12, 2024, which is hereby incorporated by reference in its entirety.

### FIELD

Embodiments relate to a method for generating a motion-corrected magnetic resonance image dataset, to a computer program and to a magnetic resonance imaging apparatus.

### BACKGROUND

Patient motion is one of the most common and costly artifacts in Magnetic Resonance Imaging (MRI) and may seriously degrade the diagnostic quality of magnetic resonance (MR) exams.

Fast imaging protocols reduce the impact of motion. For example, parallel imaging techniques, as summarised in J. Hamilton, D. Franson, and N. Seiberlich “Recent Advances in Parallel Imaging for MRI” Prog. Nucl. Magn. Reson. Spectrosc., vol. 101, pp. 71-95, 2017, exploit the properties of modern multi-channel coil arrays to separate aliased pixels in the image domain or to estimate missing k-space data, using knowledge of nearby acquired k-space points, in order to allow scan time reduction by sampling a smaller number of phase encoding lines in k-space.

Some retrospective motion correction techniques involve measuring the motion by additional image navigator scans. The desired motion information is obtained by registering the individual navigator images with one another. However, navigator-based approaches are limited to specific sequences/contrasts that provide enough dead time to accommodate for the repeated acquisition of navigators.

By contrast, navigator-free retrospective motion correction techniques attempt to estimate the motion trajectory and motion-free image from the acquired magnetic resonance data itself. By including motion parameters into the MR forward model, these techniques account for the patient's motion in the final image reconstruction and therefore reduce motion artifacts. This may for example be accomplished by minimizing the data consistency error of a parallel “imaging+motion” forward model, as described in L. Cordero-Grande, R. Teixeira, E. Hughes, J. Hutter, A. Price, Hajnal, “Sensitivity Encoding for Aligned Multishot Magnetic Resonance Reconstruction,” IEEE Trans. Comput. Imaging, vol. 2, no. 3, pp. 266-280, 2016 and M. W. Haskell, S. F. Cauley, and L. L. Wald, “TArgeted Motion Estimation and Reduction (TAMER): Data consistency based motion mitigation for MRI using a reduced model joint optimization,” IEEE Trans. Med. Imaging, vol. 37, no. 5, pp. 1253-1265, 2018. When the “imaging+motion” model and the underlying imaging protocol also include parallel imaging techniques that make use of the complex sensitivity profiles of multi-channel coil arrays, such as SENSE (SENSitivity Encoding) or ASSET (Array coil Spatial Sensitivity Encoding), it is referred to as “SENSE+motion” model.

In the TAMER method, the motion and image vector are jointly estimated via an inversion of the “imaging+motion” forward model. This corresponds to a large-scale non-linear optimization problem that is typically computationally very expensive. Previously proposed methods alternate between optimizing just the image or the motion parameters while assuming the other to be fixed (see L. Cordero-Grande in Magn. Reson. Med.), instead of updating all optimization variables at once. Nevertheless, repeated updates of the imaging voxels lead to long computation times that have so far impeded wide-spread clinical adoption.

In “Scout accelerated motion estimation and reduction (SAMER)”, Magn. Reson. Med., vol. 87, pp. 163-178, 2022, https://doi.org/10.1002/mrm.28971, D. Polak, D. N. Splitthoff, B. Clifford, W.-C. Lo, S. Huang, J. Conklin, L. L. Wald, K. Setsompop and S. Cauley propose a technique that utilizes a single rapid scout scan to drastically reduce the computational cost of motion estimation. The scout image contains center of k-space information that is compared against the k-space data of the actual MR acquisition for each shot, to derive the subject's motion. This corresponds to registration of the k-space data with the scout image in k-space. This strategy is used to completely avoid the alternating optimization of subject motion and image volume, that is otherwise required in retrospective motion correction techniques. In the SAMER-technique, a motion trajectory of the subject is first estimated, and the motion trajectory is then used in a motion-aware parallel image reconstruction, using e.g. a “SENSE+motion” forward model, to yield the motion-mitigated image. This reduces the computational costs by several orders of magnitude, when compared to established alternating optimization methods.

In D. Polak, J. Hossbach, D. N. Splitthoff et al. “Motion guidance lines for robust data consistency-based retrospective motion correction in 2D and 3D MRI”, Magn. Reson. Med. 2023:1-14, doi: 10.1002/mrm.29534, D. Polak et al. have extended the SAMER method to include the repeated acquisition of a small number of motion guidance lines in each shot, that are used for motion estimation by being compared with the data from the scout scan. The SAMER extension no longer requires changes to the standard sequence ordering, i.e. one may retain the normal linear acquisition order of e.g. MPRAGE. This allows for very rapid and fully separable estimation of motion parameters shot-by-shot.

In the above cited methods for retrospective motion correction, a rigid-body motion model is often used for motion estimation and artifact correction; however, this rigid-body assumption is often not valid. Rather, the human body has multiple articulations and joints, so that several body parts of the subject may move non-rigidly and/or independently from one another. Neglecting this aspect and treating the entire field-of-view (FOV) as a rigid body may lead to inaccurate motion estimates and therefore motion artifacts in the final image.

### BRIEF SUMMARY AND DESCRIPTION

The scope of the embodiments is defined solely by the appended claims and is not affected to any degree by the statements within this summary. The present embodiments may obviate one or more of the drawbacks or limitations in the related art. Independent of the grammatical term usage, individuals with male, female or other gender identities are included within the term.

Embodiments overcome these problems of retrospective motion correction techniques in MRI. Embodiments provide a method for providing a motion-corrected MR image having fewer motion artifacts.

In an embodiment, a method for generating a motion-corrected magnetic resonance image dataset of a body region of a subject is provided the method including: receiving magnetic resonance data acquired of the body region using a magnetic resonance imaging protocol, in which spatial encoding is performed using phase encoding gradients along at least one phase encoding direction, and frequency encoding gradients along a readout direction, wherein k-space is sampled during the imaging protocol in a plurality of k-space lines oriented along the readout direction, and having different k-space positions in the at least one phase encoding direction; optionally receiving information on the body region covered by the magnetic resonance image dataset; weighting at least part of the received magnetic resonance data by reducing the signal originating from parts of the body region that are expected to have undergone non-rigid and/or independent motion during the acquisition, thereby producing weighted magnetic resonance data; and estimating the motion-corrected image dataset by minimizing the data consistency error between the magnetic resonance data acquired in the imaging protocol and a forward model described by an encoding matrix, wherein the encoding matrix includes motion parameters, Fourier encoding, and optionally subsampling and/or coil sensitivities of a multi-channel coil array, wherein the estimation includes at least one step of estimating motion parameters from the weighted magnetic resonance data.

Although the rigid-body assumption may not be correct for the entire field-of-view (FOV), it often is a good approximation for a part of the FOV. Another part of the FOV may include body parts that do not move rigidly, or that move rigidly but independently from the part for which the rigid-body assumption holds. For example, in head imaging, the skull/brain typically moves rigidly, while the mouth/jaw/neck area may move non-rigidly and/or independently from the skull/brain area. In such instances, the retrospective motion correction may profit, if the estimation of the motion parameters is performed only on data acquired from a body part that does move rigidly—in this example, the skull/brain portion of the image. For example, the estimation of the motion parameters is done on the body part that is of most diagnostic importance. In the case of head imaging, this usually is the skull/brain, whereas the mouth/jaw/neck just happen to be within the FOV. Thus, the signal originating from body parts that are expected to move non-rigidly and/or independently from the body part that is of most interest, should be reduced when estimating motion parameters.

This is done by weighting at least part of the received magnetic resonance data by reducing the signal originating from parts of the body region that are expected to have undergone non-rigid and/or independent motion during the acquisition, thereby producing weighted magnetic resonance data; and estimating motion parameters from the weighted magnetic resonance data. The step of estimating motion parameters is usually done in the course of the image reconstruction including retrospective motion correction. Within the image reconstruction, for example estimating motion parameters and calculation of the motion-corrected image are two separate steps. The image reconstruction may be performed by any data-driven retrospective motion correction technique, for example by one of the techniques cited above (SAMER, TAMER etc.).

Thereby, the stability and robustness of retrospective motion correction is improved by removing/reducing non-rigid signal sources from the motion estimation. This is achieved by removing or at least down-weighting signal originating from non-rigid and/or independently moving areas in the imaging FOV. Embodiments may also benefit other clinical applications in which motion correction has so far not been successful by retrospective motion correction, for example MR imaging of body parts that are subject to hard-to-correct motion types, e.g., liver, prostate, etc.

The imaging protocol used in the acquisition of the magnetic resonance data may be based on any type of imaging sequence, for example a spin-echo, turbo spin-echo, or gradient echo sequence. It may have T1-weighted, T2-weighted or other contrast. It may be a steady state sequence such as FLASH, or a non-steady-state sequence, i. e. one in which the signal intensity or contrast varies over an echo train for example due to T1 and/or T2 relaxation, such as MPRAGE (Magnetization Prepared Rapid Gradient Echo Imaging) or TSE. A further example of the imaging protocol is a SPACE sequence (Sampling Perfection with Application optimized Contrast using different flip angle Evolution), but other types of imaging sequences are also possible.

The thereby acquired magnetic resonance image dataset, also referred to as “image dataset” or “image”, may be a three-dimensional (3D) image dataset or a two-dimensional (2D) image dataset. A 3D image dataset is acquired using two phase encoding directions, wherein a 2D image dataset includes one or for example a stack of 2D slices. A 2D image dataset is acquired using a slice selection gradient typically followed by phase encoding in one in-plane direction and frequency encoding in the other in-plane direction. The image dataset may be acquired for diagnostic purposes and thus has a high spatial resolution of, for example, an in-plane resolution of 0.3 mm-3 mm, for example 0.4-2 mm. The voxel size may be for example e.g. 0.5 to 12 mm³, for example 2 to 8 mm³. For a 2D image, the in-plane resolution may for example be 0.3 mm-2 mm, for example 0.4-1.2 mm.

The method may be executed on magnetic resonance data acquired by any medical or other MRI apparatus, also referred to as MR scanner herein. The subject may be human or animal, for example a patient to be examined. The image dataset is for example acquired from a body part that is subject to undesired motion, for example the head/neck are, a limb such as a leg, arm, knee, hand, or a part subjected to breathing motion such as the thorax or abdomen.

The method may include a step of receiving information on the body region covered by the magnetic resonance image dataset. In case this information is not given, it may be determined automatically. From the information on the body region, the method may derive which part of the magnetic resonance data needs to be reduced, in order to suppress non-rigid signal sources. The method may rely on prior knowledge on how the different parts of the body are expected to move. For example, the head moves rigidly, whereas the jaw and neck area may move non-rigidly. The information on the body region may be obtained from various sources. For example, it may be derived from prior knowledge about the image to be acquired, for example from the diagnostic question. For example, if the patient is scheduled for a head scan, the MRI apparatus already knows that the body region will be the head and neck. It will also know the orientation of the patient to be head-first within the sensitive volume of the MR scanner, i.e. the neck is in the lower part of the FOV and the head in the upper part of the FOV. In other embodiments, the information of the body region may be derived from an MR image, for example a low-resolution image acquired previously from the body region. Alternatively, the information of the body region may be derived from the magnetic resonance data acquired in the imaging protocol (possibly before it is motion-corrected.

According to an embodiment, the parts of the body region that are expected to have undergone non-rigid motion during the acquisition, are determined from a magnetic resonance image of the body region, for example from a low-resolution image. Such low-resolution image may be processed by an algorithm that is programmed or trained to recognize the depicted anatomy. The algorithm may be an artificial intelligence algorithm, for example a deep learning algorithm.

“Reducing” the signal originating from parts of the body region that are expected to have undergone non-rigid and/or independent motion, may mean a full suppression of the relevant signal, i.e. setting it to 0. It may also mean a partial reduction, wherein the signal amplitude is reduced for example to less than 60%, for example less than 50%, more preferred less than 30% of its original (as acquired) value. The “reducing” may also include a weighting using a function, for example a pre-determined function. Examples will be described herein below.

The magnetic resonance data acquired from the body region during the imaging protocol is designed to be reconstructed using data-driven retrospective motion correction techniques, such as TAMER, SAMER, or the technique disclosed by D. Polak et al. in Magn. Reson. Med. 2023:1-14.

The motion parameters are for example rigid-body motion parameters, wherein one motion state is described by three translational and three rotational parameters. In some embodiments, they may also be non-rigid motion parameters, such as affine motion parameters. Affine motion parameters include 12 parameters for each motion state and describe also states of compression and torsion. The estimated motion parameters for example include a motion trajectory, i.e. a sequence of motion states of the body region during the acquisition of the imaging protocol. The motion trajectory may be estimated from sets of motion guidance lines acquired throughout the imaging sequence and a low-resolution scout image, according to the technique disclosed by D. Polak et al. in Magn. Reson. Med. 2023:1-14.

According to an embodiment, the estimation includes at least one first step of estimating motion parameters from the weighted magnetic resonance data, while using a fixed estimate for the image dataset, and at least one second step of estimating the motion-corrected image dataset by minimizing the data consistency error between the magnetic resonance data acquired in the imaging protocol and the forward model described by an encoding matrix, wherein the encoding matrix includes the motion parameters estimated in the first step. For example, the algorithm may alternate between optimizing just the image or the motion parameters while assuming the other to be fixed (see L. Cordero-Grande in Magn. Reson. Med.), instead of updating all optimization variables at once. In other embodiments, a SAMER method is used, wherein the motion parameters, for example a motion trajectory, is estimated once, using the scout image, and the motion parameters are then used in a motion-aware parallel image reconstruction, using e.g. a “SENSE+motion” forward model, to yield the motion-mitigated image. This embodiment is advantageous because the motion parameters are estimated from the weighted magnetic resonance data, in which signal contributions from non-rigidly moving regions are reduced, and thus the motion parameters will be more accurate.

According to an embodiment, the step of weighting at least part of the received magnetic resonance data includes weighting the voxel data of at least some k-space lines depending on a voxel location in readout direction, for example by suppressing the voxel data originating from readout locations above or below a threshold location. This method is referred to herein as “readout segmentation”. It is particularly effective when used in combination with the SAMER method, because SAMER relies on the motion parameters being derived from of a small number of additional k-space lines, also referred to as guidance lines. In this case, the weighting is done on the guidance lines, i.e. the “at least some k-space lines” are the guidance lines. A set of guidance lines includes a few (e.g. 2 to 16, for example 4-8) k-space lines (fully sampled in readout direction) and therefore does not provide enough spatial image information to allow a segmentation of the image in all three spatial directions. However, in readout direction (x), the resolution may be high without any time penalty, and therefore it is possible to segment the guidance lines in readout direction. This segmentation, followed by weighting or suppression, is for example done in the image domain, not in k-space domain. For the further processing, the weighted MR data may be transformed back into k-space notation. Therefore, it is possible to weigh the guidance line data by reducing the contribution from parts of the body region that should not contribute to the estimation of the motion trajectory in one spatial direction. For example, one may “cut off” a part of the image in readout direction, so that this part of the image does not contribute to the motion estimation. For example, the neck portion may be cut off. When imaging e.g. the liver, an image portion including intestines may be suppressed. According to an embodiment, the imaging protocol is adapted such that the readout direction is oriented such that those portions of the body part that move non-rigidly and/or independently are on one side of the FOV in readout direction, so that they may be effectively segmented.

In this embodiment, the influence of non-rigid signal sources (e.g., neck/mouth) may be reduced by restricting the SAMER motion optimization to readout (x) voxel locations that primarily exhibit rigid-body motion (e.g., the skull/brain in head imaging).

The weighting may include a complete data suppression or exclusion, i.e. setting the signal to 0. More generally, the weighting may include a weighting using a function of the readout voxel location. The function may have a threshold location, wherein the voxels on one side of the threshold (=above/below the threshold) are set to 0, whereas the voxels on the other side of the threshold are retained. The function may also have a smoother transition at a threshold location, e.g. a tanh function. In an embodiment, about 40-85%, for example 55-75%, of the readout voxels are chosen for motion estimation, while the rest is suppressed (set to 0), i.e. discarded for the purposes of motion estimation.

According to an embodiment, the voxel data originating from readout locations above or below a threshold location are reduced, for example suppressed. This threshold may be determined specially for every subject and imaging protocol, e.g., based on a low-resolution MR image, such as a pre-scan. Such MR image may be processed by an algorithm to determine a suitable threshold location in readout direction.

According to an embodiment, the threshold location is determined from a center of mass of a magnetic resonance image of the body region. The MR image may for example by a low resolution scout image, for example a pre-scan.

Thus, a suitable reference point for such a thresholding approach is to use the center of mass of a projection image, wherein the projection is in the phase-encode directions, and the center of mass along the readout direction on the projection image is determined. The center of mass may be determined from the guidance lines, or from other magnetic resonance data acquired from the body region, for example from a low-resolution MR image. The threshold may be set at a pre-determined distance above or below the center of mass. It may be set at a pre-determined percentage of the FOV above or below the center of mass. There may be several thresholds, for example one in the upper part of the FOV and one in the lower part of the FOV, wherein the voxel data above the upper threshold and the voxel data below the lower threshold are suppressed. Thus, parts of the image at both ends of the FOV in readout direction may by “cut off” for the purposes of motion estimation. The position of each threshold location may be determined independently; thus, the amount of readout cropping (thresholding) may vary between the upper and lower FOV boundary.

According to an embodiment, the body region is the head of the subject and the readout direction is oriented along the top-bottom direction of the subject, and wherein the step of weighting at least part of the received magnetic resonance data includes suppressing the voxel data originating from readout locations covering the neck and/or mouth of the subject. Thereby, the motion trajectory from the rigidly moving skull/brain area may be accurately determined, by excluding the non-rigid jaw, neck and mouth. This is acceptable because a head scan is usually done in order to examine the brain, that is within the skull area.

According to an embodiment, the magnetic resonance data is acquired using a multi-channel coil array, and wherein the step of weighting at least part of the received magnetic resonance data includes mixing the receive channels of the multi-channel coil array so as to minimize signal contributions from those parts of the body region that are expected to have undergone non-rigid motion during the acquisition. This approach is also referred to as “optimized mixing of receive channels”. The coil sensitivity profile of modern multi-channel coil arrays provides additional spatial encoding information that may be leveraged to suppress confounding signal sources, as generally described in L. W. S. Cauley, D. Polak, et al., “Geometric Coil Mixing (GCM) to Dampen Confounding Signals in MRI Reconstruction,” Int. Soc. Magn. Reson. Med. Montr., vol. 0449, 2019. This concept may be applied to scout and/or guidance line-based motion estimation, by determining an optimized mixing of the receive channels that minimizes signal from undesired body regions, for example the parts of the body region that are expected to have undergone non-rigid and/or independent body motion (e.g., mouth/neck). The mixing may be performed by applying a channel mixing matrix. In an embodiment, the channel mixing matrix may simply remove/turn off coil channels that are particularly sensitive to undesired regions of the FOV. In other embodiments, the channel mixing matrix may include more general weighting of the receive channels. The mixing matrix may again be computed based on a low-resolution scout image or pre-scan. Also by this method, the motion parameters may be determined more accurately and with less contribution from non-rigid parts of the body region.

In an embodiment, readout segmentation and optimized mixing of receive channels are both used. The combined effect of readout segmentation and optimized mixing of receive channels is particularly advantageous, since it allows good localization and suppression of non-rigid signal sources and may substantially improve SAMER motion mitigation.

According to an embodiment, the weighting step is performed multiple times, each time to reduce the signal originating from different parts of the body region, wherein the different parts are expected to have undergone different motion during the acquisition, and wherein the step of estimating the motion-corrected image dataset includes estimating different motion parameters for the different parts of the body region. Thereby, different, independent motion trajectories may be determined for multiple target regions. For example, in head imaging, one may estimate separate motion trajectories for the brain and the neck/mouth. Similarly, the spine may be divided into multiple sections. This breaks up the complex non-rigid spine motion into a simpler motion model. The individual motion trajectories for example include rigid-motion parameters. They may also include non-rigid motion parameters, for example affine motion parameters (including stretching and compressing motion). However, while it may be desirable to use a higher order motion model (e.g., affine transformation having 12 degrees of freedom), it may be for example in many instances to use a sufficiently low-dimensional model to provide the best trade-off between accuracy and robustness of the motion estimation/correction. Therefore, rigid-body motion parameters are preferred in many embodiments. According to an embodiment, either or both of readout segmentation and optimized mixing of receive channels are repeated to perform motion estimation/correction for multiple target regions.

The different motion trajectories for the different parts of the body region may be used in various ways. According to a first embodiment, the different motion parameters for the different parts of the body region are used to produce a combined motion field for the complete body region, using boundary conditions in the transitional zones, wherein the combined motion field is used in the estimation of the motion-corrected image dataset. The boundary conditions may ensure a smooth transition in motion parameters between the different parts of the body region, that simulates the behavior of the body, and that is useful in obtaining a smooth reconstructed image, without “fault lines” between the different parts of the body region.

According to a second embodiment, the step (d) of estimating the motion-corrected image dataset includes estimating motion-corrected part-images of the different parts of the body region, wherein each part-image is based on different motion parameters, followed by a step of combing the part-images to a complete motion-corrected image. Thus, in this embodiment, the different motion trajectories for the different parts of the body region are used to reconstruct separate image parts, referred to as part-images, each part-image corresponding to an independently moving part of the body. These several part-images have to be “stitched together” in order to yield a smooth image, because otherwise there would be visible “fault lines” between the different part-images. The combination may be done by a registration step. For example, the part-images may be deliberately reconstructed so that they overlap one another, and the overlap regions may be registered with one another. Thereby, a complete motion-corrected image may be reconstructed, wherein different parts of the image have undergone different motion trajectories.

According to an embodiment, the weighting step is performed on sets of additional k-space lines acquired within a central region of k-space during the magnetic resonance imaging protocol. The sets of additional k-space lines are used for motion estimation, for example to detect movement of the object throughout the imaging sequence, because for this purpose it is useful to have the central area of k-space sampled at regular intervals. This is disclosed e.g. D. Polak et al. in Magn. Reson. Med. 2023:1-14. “Additional” means that the k-space lines are acquired in addition to those that are required under the imaging protocol to acquire the MR image, i.e. they are redundant when it comes to image reconstruction. The sets of additional k-space lines are typically at the same position in k-space at each acquisition, but this is not mandatory.

In useful embodiments, a set of guidance lines is acquired once or a few times in every echo train. An “echo train”, also referred to as “shot”, includes a plurality of MR echoes, e.g. spin echoes and/or gradient echoes. During each echo, a k-space line is acquired. An echo train may be acquired after a single preparation pulse, such as an inversion pulse. In most sequences, an echo train includes a preparation pulse, and then all echoes have their own excitation/refocusing pulses, except in echo-planar imaging. The guidance lines for example provide sufficient spectral information to perform accurate motion estimation and retrospective motion correction. By weighting the guidance lines as proposed, the motion estimation is improved.

According to an embodiment, the magnetic resonance data has been acquired using a method including acquiring a low-resolution scout image dataset of the body region, and acquiring sets of additional k-space lines within a central region of k-space at—at least approximately—regular intervals during the imaging protocol. The low-resolution scout image for example covers the same field-of-view as the magnetic resonance image dataset. Thus, in case of a 3D imaging, it covers the same volume. In case the image dataset is a stack of 2D slices, the scout image includes also a stack of low-resolution 2D slices. However, it is possible that the low-resolution scout includes fewer slices than the high-resolution image, for example only every second or third slice. The low-resolution scout image may have a spatial resolution of 2-8 mm, for example 3-5 mm, for example 4 mm, in the phase-encoding direction(s). For example, the acquisition of the scout is very rapid, requiring e.g. 1-5 sec, for example 1-2 secs. It is for example acquired once before or after the imaging protocol, for example before.

According to an embodiment, the method includes receiving a low-resolution scout image dataset of the body region, and receiving sets of additional k-space lines within a central region of k-space at—at least approximately—regular intervals during the imaging protocol, weighting the sets of additional k-space lines by reducing the signal depending on a voxel location in readout direction, so as to produce weighted additional k-space lines; estimating the motion-corrected image dataset by minimizing the data consistency error between the magnetic resonance data acquired in the imaging protocol and the forward model, wherein the estimation includes: in a first step, estimating motion parameters for each set of weighted additional k-space lines by minimizing the data consistency error between the weighted additional k-space lines and the forward model using the low-resolution scout scan as an estimate for the image dataset; and in a second step, estimating the motion-corrected image dataset by minimizing the data consistency error between the magnetic resonance data acquired in the imaging protocol and a forward model described by an encoding matrix, wherein the encoding matrix includes the motion parameters estimated in the first step for each set of weighted additional k-space lines, Fourier encoding, and optionally subsampling and/or coil sensitivities of a multi-channel coil array.

The sets of additional k-space lines are acquired in a central region of k-space, wherein the central region is for example covered by the low-resolution scout image. However, each set of additional k-space lines typically includes fewer k-space lines than would be required to reconstruct a scout image. For example, a set of k-space lines may include 1 to 8, for example 1-4, k-space lines for each 2D slice of a 2D image dataset. In case the image dataset is a 3D image dataset, a set of k-space lines may include 2 to 32, for example 3-8, k-space lines. The set of additional k-space lines is acquired repeatedly during the imaging protocol, namely at—at least approximately—regular intervals. “At least approximately”, when used in this application, may mean within ±15%, for example within ±10%, most preferred within ±5%. Each set of additional k-space lines is intended to provide information on the position of the subject at the point in time at which the set was acquired. Therefore, the intervals in which the sets are acquired are for example set to a time that gives a sufficiently high temporal resolution on the one hand, and on the other hand does not take up too much of the total scan time. The interval at which the sets of additional k-space lines are acquired is for example between 100 ms and 3000 ms, more preferred between 5000 ms and 1500 ms. In 3D imaging protocols, typically one set of guidance lines is acquired per TR, e.g., every 1-3 seconds. In 2D imaging protocols, guidance lines are for example acquired in every slice, e.g. every 80-250 ms, however, to estimate one motion state, guidance line information from multiple slices needs to combined to obtain through-plane information. Hence, the temporal resolution in 2D may also be in the 1-2 sec range.

The estimation is for example carried out in two steps: in a first step, motion parameters are estimated for each set of guidance lines by minimizing the data consistency error of the forward model, that may amount to a comparison with the low-resolution scout image. In a second step, the motion-corrected image is estimated using the motion parameters estimated in the first step. Thereby, alternating between repeated updates of the otherwise coupled optimisation variables x (image vector) and 0 (motion parameters) is avoided. Rather, the rapid scout image dataset is used as an image estimate x. This leads to a highly efficient optimisation problem that is fully separable across the echo trains and does not require repeated updates of x, that may include millions of imaging voxels. The minimisation problem may be derived from a SENSE parallel imaging forward model, as described in K. P. Pruessmann, M. Weiger, M. B. Scheidegger, and P. Boesiger, “SENSE: sensitivity encoding for fast MRI,” Magn. Reson. Med., vol. 42, no. 5, pp. 952-962, 1999, with rigid body motion parameters included (“SENSE+motion”). The overall method is described in Magn. Reson. Med. 2023:1-14, doi: 10.1002/mrm.29534, that is incorporated herein by reference.

According to a further aspect, a computer configured to generate a motion-corrected magnetic resonance image dataset is provided. The computer may be any computer including a sufficiently powerful processing unit, that may be a CPU or GPU, or several such processing units. Accordingly, the computer may be a PC, a server, a console of an MRI apparatus, but it also may be a computer that is remote from the MRI apparatus, it may be connected with it through the internet. Accordingly, the computer may also be a cloud computer, a remote server etc. The computer may also be a mobile device, such as a laptop, tablet computer or mobile phone.

According to a further aspect, a computer program is provided that includes program code, that causes a computer—such as the computer described herein—to execute the method, for example to carry out an algorithm the method for generating a motion-corrected magnetic resonance image dataset.

According to a further aspect, a non-transitory computer-readable medium containing a computer program as described herein is provided. The computer-readable medium may be any digital storage medium, such as a hard disc, a cloud, an optical medium such as a CD or DVD, a memory card such as a compact flash, memory stick, a USB-stick, multimedia stick, secure digital memory card (SD) etc.

In a further aspect, a magnetic resonance imaging apparatus is provided that includes a radio frequency controller configured to drive an RF-coil, for example including a multi-channel coil-array, a gradient controller configured to control gradient coils, and a control unit configured to control the radio frequency controller and the gradient controller to execute the imaging protocol. The MRI apparatus further includes a processing unit configured to execute the method described herein. The MRI-apparatus may be a commercially available MRI-apparatus that has been programmed to perform the method.

All features and advantages disclosed with regard to the method for generating a motion-corrected MRI dataset may be provided in the MRI apparatus, computer program and computer-readable storage medium according to other aspects and vice versa.

### BRIEF DESCRIPTION OF THE FIGURES

FIG. 1 depicts a schematic representation of an MRI apparatus according to an embodiment.

FIG. 2 depicts a schematic representation of a three-dimensional k-space according to an embodiment.

FIG. 3 depicts a sequence diagram of an MRRAGE sequence with motion guidance lines according to an embodiment.

FIG. 4 depicts an alternating optimization algorithm according to an embodiment.

FIG. 5 depicts a SAMER optimization according to an embodiment.

FIG. 6 depicts a sagittal MR image through the head according to an embodiment.

FIG. 7 depicts a segmentation of the brain from the sagittal image of FIG. 6 according to an embodiment.

FIG. 8 depicts the content of a set of guidance lines in image space according to an embodiment.

### DETAILED DESCRIPTION

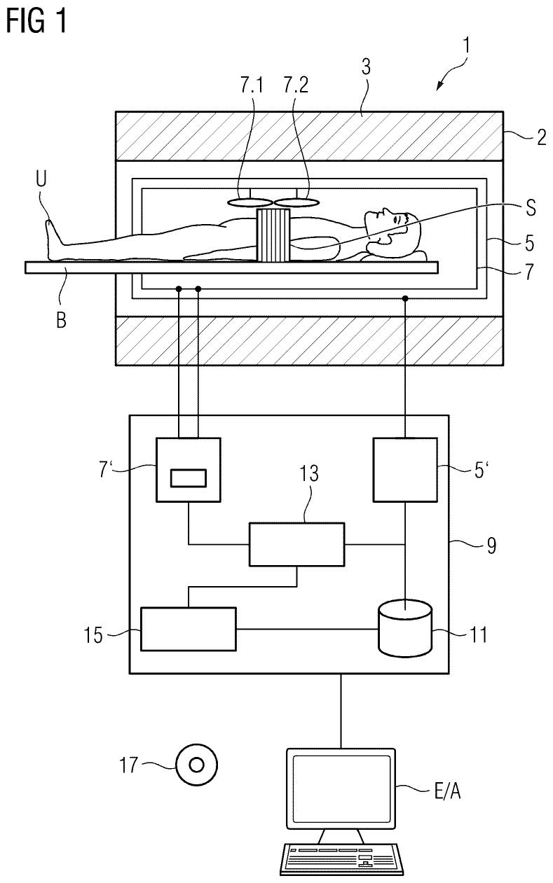

FIG. 1 schematically depicts a magnetic resonance (MR) apparatus 1. The MR apparatus 1 includes an MR data acquisition scanner 2 with a magnet 3 that generates the constant magnetic field, a gradient coil arrangement 5 that generates the gradient fields, one or several radiofrequency (RF) antennas 7 for radiating and receiving RF signals, and a control computer 9 configured to perform the method. The radio-frequency antennas 7 may include a multi-channel coil array including at least two coils, for example the schematically shown coils 7.1 and 7.2, that may be configured to transmit and/or receive RF signals (MR signals).

In order to acquire MR data from an examination subject U, for example a patient or a phantom, the subject U is introduced on a bed B into the measurement volume of the scanner 2. MR data may be acquired using a method according to an embodiment from a stack S of 2D slices. The control computer 9 controls the MR apparatus 1, and the gradient coil arrangement 5 with a gradient controller 5′ and the RF antenna 7 with a RF transmit/receive controller 7′. The RF antenna 7 has multiple channels corresponding to the multiple coils 7.1, 7.2 of the coil arrays, in which signals may be transmitted or received. A control unit 13 of the control computer 9 is configured to execute all the controls and computation operations required for acquisitions. The control computer 9 also has a processing unit 15 for performing the method. Intermediate results and final results required for this purpose or determined in the process may be stored in a memory 11 of the control computer 9. A user may enter control commands and/or view displayed results, for example image data, an input/output interface E/A. A non-transitory data storage medium 17 may be loaded into the control computer 9 and may be encoded with programming instructions (program code) that cause the control computer 9, and the various functional units thereof described above, to implement any or all embodiments of the method described herein.

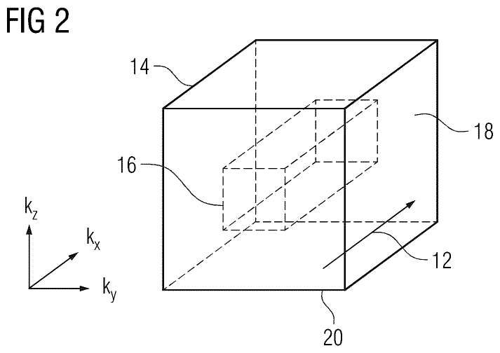

FIG. 2 depicts a three-dimensional k-space 14 having dimension kx in frequency encoding (readout) direction, and ky and kz in the phase encode plane 20. A k-space line acquired during one echo is illustrated at 12. The k-space volume 14 includes a central region 16 and a periphery 18. The additional k-space lines as well as the k-space lines acquired for the low-resolution scout are located in the central region 16. In the phase encode plane 20, the central region 16 may cover about 1/12 to 1/16 in each direction, i.e. less than 1/100 of the total square phase encode plane 20.

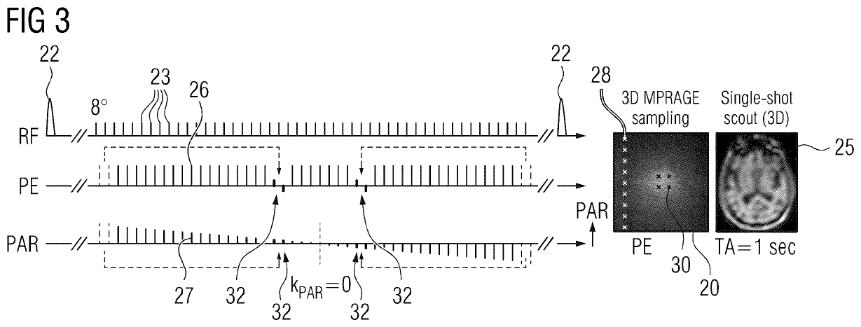

FIG. 3 depicts a 3D MPRAGE sequence with motion guidance lines as disclosed in Magn. Reson. Med 2023:1-14, doi: 10.1002/mrm.29534. On the left, a sequence diagram is shown indicating the RF pulses on the top, the phase encode (PE) gradients in the first direction in the middle, and the phase encode gradients in the second direction (PAR for partition) at the bottom. As usual for MPRAGE, an echo train starts with a 180° inversion pulse 22, followed by a wait time and then by a series of low flip angle (here 8°) pulses 23, wherein a k-space line is acquired after each pulse 23. The ordering is linear, wherein after each readout, phase encode gradient blips 26, 27 are applied in the PE and PAR directions, so that the phase encode plane 20 is sampled in a straight line, as illustrated at 28, wherein each point 28 indicates a k-space line oriented perpendicular to the phase encode plane 20. Four echoes from the regular imaging protocol were removed from the echo train to accommodate four guidance lines 30 located near the center of k-space. Alternatively, the guidance lines 30 are acquired in addition to the normal imaging data, i.e. the echo train is made slightly longer. The respective phase encode gradients are illustrated at 32. The echo train may have e.g. 150 to 240 echoes. It may be e.g. 0.5 s to 1.5 s long. The corresponding 3D MPRAGE low-resolution scout image 25 may be acquired in a single shot, that requires only an acquisition time TA of about 1 sec.

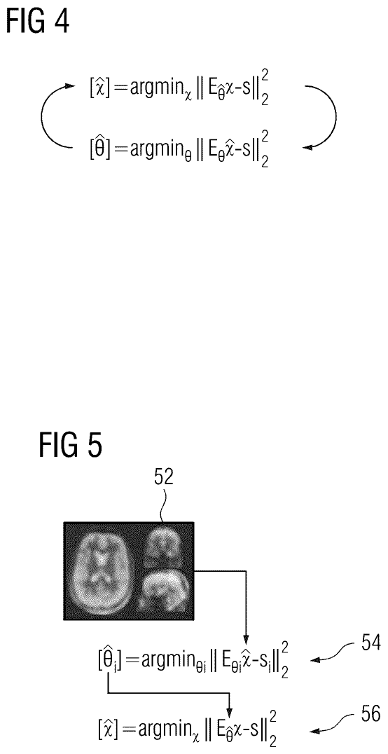

A retrospective motion correction technique that may be used to estimate the motion states, will now be described with reference to FIGS. 4 and 5. The mathematical model used is an extension of SENSE parallel imaging, as described in the above-cited paper by K. P. Pruessmann et al., with rigid-body motion parameters included into the forward model. The forward model or encoding operator E_{θ} for a given patient motion vector θ (including motion parameters over time, for example a motion trajectory) relates the motion-free image x to the acquired multi-channel k-space data s. At each time point i that is considered, e.g. the acquisition time of the sets of guidance lines, the subject's position is described by a new set of six rigid-body motion parameters θi that describe the 3D position of the object. Accordingly, the multi-channel k-space data sᵢ acquired at time point i may be related to the 3D image volume x through image rotations Rᵢ, image translations Tᵢ, coil sensitivity maps C, Fourier operator F and under-sampling mask Mᵢ by the following formula 1:

$${s}_{i} = {E}_{{θ}_{i}} x = {M}_{i} F C {T}_{{θ}_{i}} {R}_{{θ}_{i}} x$$

In some retrospective motion correction methods, as illustrated in FIG. 4, both the motion-corrected image vector x and the motion trajectory θ are estimated by performing an alternating, repeated optimization between the image vector (formula 2) and the motion vector (formula 3):

$$[ \hat{x} ] = arg {min}_{x} {‖ {E}_{\hat{θ}} x - s ‖}_{2}$$

$$[ \hat{θ} ] = arg {min}_{θ} {‖ {E}_{θ} \hat{x} - s ‖}_{2}$$

In the second step, the weighted magnetic resonance data should be used. This method is possible but computationally demanding as repeated updates of x (millions of imaging voxels) are needed.

Using one or several ultra-fast low-resolution scout scans 52, the motion trajectory may be directly estimated, as illustrated in FIG. 5, thus avoiding the time-consuming alternate optimization. The scout image 52, designated by \tilde{x}, approximates the motion-free image volume \hat{x} and each motion state may be determined independently by minimizing the data consistency error of the forward model 54:

$$[ {\hat{θ}}_{i} ] = arg {min}_{{θ}_{i}} {‖ {E}_{{θ}_{i}} \tilde{x} - {s}_{i} ‖}_{2}$$

The weighted magnetic resonance data is used in this step 54. For example, the weighted magnetic resonance data includes guidance lines. Thus, the additional k-space lines are used in this first step of the optimization. For example, only the guidance lines are used.

For the final image reconstruction, the motion parameters θi from each set of guidance lines are combined and the motion-mitigated image is obtained from solving a standard least-squares problem 56:

$$[ \hat{x} ] = arg {min}_{x} {‖ {E}_{\hat{θ}} x - s ‖}_{2}$$

This strategy completely avoids the difficult non-linear and non-convex joint optimization that contains millions of unknowns, as it for example only considers six rigid body parameters per motion optimization, and it does not require computationally costly full or partial updates to the image.

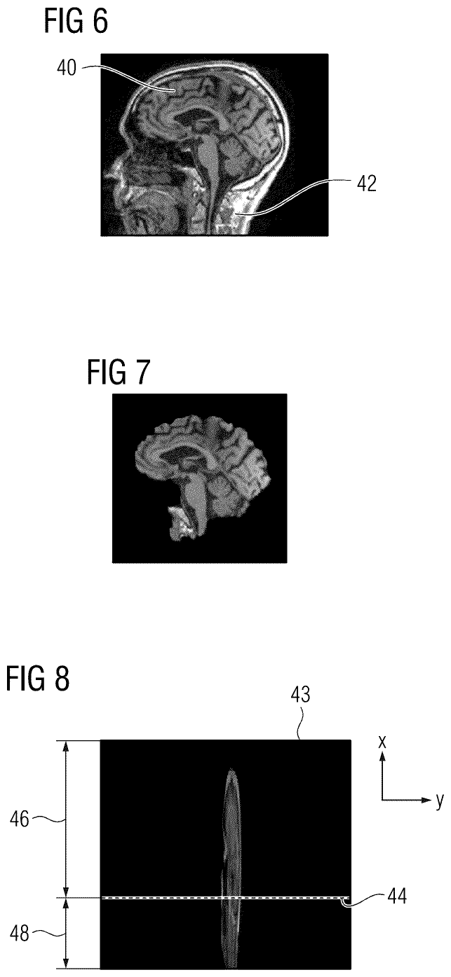

FIG. 6 depicts a rigidly moving body part 40, in this case the skull, as visible on a sagittal MR image through the head. The neck area 42, by contrast, may move non-rigidly and/or independently from the skull portion.

FIG. 7 depicts a segmentation of the brain from the sagittal image of FIG. 6. Full image navigator approaches would allow brain segmentation, as shown in FIG. 6, in order to remove non-rigid signal sources. However, this is not feasible in SAMER, where the motion information is obtained from a small number of motion guidance lines.

FIG. 8 depicts the concept of readout segmentation on guidance line data. The image illustrates the content of a few guidance lines, in image space, of the head depicted in FIG. 6. As may be seen the image is essentially a projection along y/z direction, but having full resolution in readout (x) direction. Even in this projection-type image, a threshold position in the readout direction, depicted at 44, may be determined, wherein the threshold separates the region 46 containing the data used for motion estimation, from the region 48, containing data of non-rigidly moving body parts. The data from area 48 is weighted down, or for example completely discarded in the motion estimation. Thereby, the SAMER motion optimization is restricted to specific readout (x) locations to remove/reduce non-rigid mouth/neck signal.

Embodiments improve the stability and robustness, especially of scout and guidance lines-based retrospective motion correction by removing/reducing non-rigid signal sources from the SAMER motion optimization. This is achieved by i) masking/re-weighting guidance line data along the readout direction and/or ii) determining an optimized receive channel mixing that removes/downweighs non-rigid areas in the imaging FOV. Both methods may be synergistically combined to achieve good localization/suppression of non-rigid signal. Moreover, the methods may be used in a multi-target approach to break up complicated non-rigid motion into simpler approximately rigid or affine motion. Knowing the motion of different target regions may be useful in a joint image reconstruction, that considers region-specific motion (e.g., head vs. neck; spine). Moreover, this approach may also benefit other clinical applications, e.g., monitoring of certain hard-to-correct motion types, e.g., liver, prostate, etc.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A method for generating a motion-corrected magnetic resonance image dataset of a body region of a subject, the method comprising:
receiving magnetic resonance data acquired of the body region using a magnetic resonance imaging protocol, in which spatial encoding is performed using phase encoding gradients along at least one phase encoding direction, and frequency encoding gradients along a readout direction, wherein k-space is sampled during the magnetic resonance imaging protocol in a plurality of k-space lines oriented along the readout direction, and having different k-space positions in the at least one phase encoding direction; and
estimating the motion-corrected image dataset by minimizing a data consistency error between the magnetic resonance data acquired in the magnetic resonance imaging protocol and a forward model described by an encoding matrix, wherein the encoding matrix includes motion parameters and Fourier encoding, wherein the estimation includes at least one step of estimating motion parameters from the magnetic resonance data.

2. The method of claim 1, further comprising:
receiving information on the body region covered by the magnetic resonance image; and
weighting at least part of the received magnetic resonance data by reducing a signal originating from parts of the body region which are expected to have undergone non-rigid and/or independent motion during the acquisition of the magnetic resonance data, thereby producing weighted magnetic resonance data.

3. The method of claim 1, wherein the encoding matrix further includes subsampling and/or coil sensitivities of a multi-channel coil array.

4. The method of claim 2, wherein the estimation further comprises estimating motion parameters from the weighted magnetic resonance data, while using a fixed estimate for the image dataset, and at least one second step of estimating the motion-corrected image dataset by minimizing the data consistency error between the magnetic resonance data acquired in the magnetic resonance imaging protocol and the forward model described by an encoding matrix, wherein the encoding matrix includes the motion parameters.

5. The method of claim 4, wherein estimating motion parameters from the weighted magnetic resonance data comprises estimating motion parameters from weighted sets of additional k-space lines acquired within a central region of k-space.

6. The method of claim 4, wherein weighting of the at least part of the received magnetic resonance data includes weighting voxel data of at least some k-space lines depending on a voxel location in readout direction by suppressing the voxel data originating from readout locations above or below a threshold location.

7. The method of claim 2, wherein the magnetic resonance data is acquired using a multi-channel coil array, and wherein weighting of the at least part of the received magnetic resonance data includes mixing receive channels of the multi-channel coil array to minimize signal contributions from those parts of the body region that are expected to have undergone non-rigid and/or independent motion during the acquisition of the magnetic resonance data.

8. The method of claim 1, wherein parts of the body region that are expected to have undergone non-rigid and/or independent motion during the acquisition of the magnetic resonance data are determined from a magnetic resonance image of the body region from a low-resolution image.

9. The method of claim 6, wherein the threshold location is determined from a center of mass of a magnetic resonance image of the body region.

10. The method of claim 2, wherein the body region is a head of the subject and the readout direction is oriented along a top-bottom or bottom-top direction of the subject, and wherein weighting of the at least part of the received magnetic resonance data includes suppressing voxel data originating from readout locations covering a neck and/or a mouth of the subject.

11. The method claim 2, wherein weighting ss performed multiple times, each time to reduce the signal originating from different parts of the body region, wherein the different parts are expected to have undergone different motion during the acquisition of the magnetic resonance data, and wherein estimating the motion-corrected image dataset includes estimating different motion parameters for the different parts of the body region.

12. The method of claim 11, wherein the different motion parameters for the different parts of the body region are used to produce a combined motion field for a complete body region, using boundary conditions in transitional zones, wherein the combined motion field is used in the estimation of the motion-corrected image dataset.

13. The method of claim 11, wherein estimating the motion-corrected image dataset includes estimating motion-corrected part-images of the different parts of the body region, wherein each part-image is based on different motion parameters, followed by combining the part-images to a complete motion-corrected image.

14. The method of claim 2, wherein weighting step is performed on sets of additional k-space lines acquired within a central region of k-space during the magnetic resonance imaging protocol.

15. The method claim 1, wherein the magnetic resonance data is acquired using a method comprising:
acquiring a low-resolution scout image dataset of the body region, and
acquiring sets of additional k-space lines within a central region of k-space at regular intervals during an imaging protocol.

16. The method of claim 15, further comprising:
weighting the sets of additional k-space lines by reducing a signal depending on a voxel location in readout direction to produce weighted additional k-space lines; and
estimating the motion-corrected image dataset by minimizing a data consistency error between the magnetic resonance data acquired in the imaging protocol and the forward model, wherein the estimation includes:
estimating motion parameters for each set of weighted additional k-space lines by minimizing the data consistency error between the weighted additional k-space lines and the forward model using the low-resolution scout scan as an estimate for the image dataset; and
estimating the motion-corrected image dataset by minimizing the data consistency error between the magnetic resonance data acquired in the imaging protocol and a forward model described by an encoding matrix, wherein the encoding matrix includes the motion parameters for each set of weighted additional k-space lines, Fourier encoding, and subsampling and/or coil sensitivities of a multi-channel coil array.

17. A non-transitory computer implemented storage medium, including machine-readable instructions stored therein for generating a motion-corrected magnetic resonance image dataset of a body region of a subject, the machine-readable instructions when executed by at least one processor, cause the processor to:
receive magnetic resonance data acquired of the body region using a magnetic resonance imaging protocol, in which spatial encoding is performed using phase encoding gradients along at least one phase encoding direction, and frequency encoding gradients along a readout direction, wherein k-space is sampled during the magnetic resonance imaging protocol in a plurality of k-space lines oriented along the readout direction, and having different k-space positions in the at least one phase encoding direction; and
estimate the motion-corrected image dataset by minimizing a data consistency error between the magnetic resonance data acquired in the magnetic resonance imaging protocol and a forward model described by an encoding matrix, wherein the encoding matrix includes motion parameters and Fourier encoding, wherein the estimation includes at least one step of estimating motion parameters from the magnetic resonance data.

18. A magnetic resonance imaging apparatus comprising:
a radio frequency controller configured to drive an RF-coil comprising a multi-channel coil array;
a gradient controller configured to control gradient coils;
a control unit configured to control the radio frequency controller and the gradient controller to execute an imaging protocol in which spatial encoding is performed using phase encoding gradients along at least one phase encoding direction, and frequency encoding gradients along a readout direction, wherein k-space is sampled during the imaging protocol in a plurality of k-space lines oriented along the readout direction, and having different k-space positions in the at least one phase encoding direction; and
a processing unit configured to receive magnetic resonance data acquired of a body region using the imaging protocol and estimate a motion-corrected image dataset by minimizing a data consistency error between the magnetic resonance data acquired in the imaging protocol and a forward model described by an encoding matrix, wherein the encoding matrix includes motion parameters and Fourier encoding, wherein the estimation includes at least one step of estimating motion parameters from the magnetic resonance data.

19. The magnetic resonance imaging apparatus of claim 18, where the processing unit is further configured to:
receive information on the body region covered by the magnetic resonance data; and
weight at least part of the received magnetic resonance data by reducing a signal originating from parts of the body region which are expected to have undergone non-rigid and/or independent motion during the acquisition of the magnetic resonance data, thereby producing weighted magnetic resonance data.
